(19) United States
(12) Patent Application Publication
(10) Pub. No.: US 2010/0220757 A1
(43) Pub. Date: Sep. 2, 2010

(54) SEMICONDUCTOR LIGHT-EMITTING ELEMENT AND PROCESS FOR PRODUCTION THEREOF

(76) Inventors: Ryota KITAGAWA, Tokyo (JP); Akira FUJIMOTO, Kawasaki-Shi (JP); Koji ASAKAWA, Kawasaki-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/717,750

(22) Filed: Mar. 4, 2010

Related U.S. Application Data
(63) Continuation of application No. PCT/JP2009/065747, filed on Sep. 9, 2009.

(30) Foreign Application Priority Data
Feb. 18, 2009 (JP) 2009-035006

(51) Int. Cl. H01S 5/02; H01L 33/10; H01L 33/00; H01L 33/44

(52) U.S. Cl. 372/44.01; 257/95; 438/29; 438/47; 257/E33.005; 257/E33.067

(57) ABSTRACT

One embodiment of the present invention provides a semiconductor light-emitting element having both high light-extraction efficiency and excellent adhesion between a light-extraction surface and a sealing resin, and it also provides a process for production thereof. This element comprises a semiconductor multilayered film and a light-extraction surface. In the multilayered film, plural semiconductor layers and an active layer are stacked. The light-extraction surface is provided on the multilayered film, and plural micro-projections are formed thereon. These micro-projections have flat top faces parallel to the multilayered film, and they can be formed by an etching process. The etching process is performed by use of a dot pattern as a mask, and the dot pattern is formed by phase separation of a block copolymer.

### CROSS REFERENCE TO RELATED APPLICATIONS

This application is based upon and claims the benefit of priority from the prior Internationa Application No. JP2009/65747 filed on Sep. 9, 2009; the entire contents of which are incorporated herein by reference.

### BACKGROUND OF THE INVENTION

1. Field of the Invention

The present invention relates to a semiconductor light-emitting element having a relief structure on its light-extraction surface, and also relates to a process for production thereof.

2. Description of Related Art

The total emission efficiency of a semiconductor light-emitting element, such as a light-emitting diode (hereinafter, referred to as “LED”), is represented by the product of its internal quantum efficiency and its light-extraction efficiency. Since the light-extraction efficiency is generally poor as compared with the internal quantum efficiency, it has been mainly attempted to improve the light-extraction efficiency so as to increase the luminance of LED.

For improving the light-extraction efficiency, it is proposed that a fine relief structure be provided on the light-extraction surface of LED to cause scattering and/or diffraction so that the interface between air and the LED may less reflect light and thereby to increase the light-extraction efficiency. The relief structure can be formed by typical methods such as electron beam lithography, nano-imprinting and micro-fabrication utilizing self-assembling of materials used therein. Among them, the micro-fabrication utilizing self-assembling has some advantages. For example, it can be applied to a surface of large area, can be performed without a large apparatus or system, and is of low cost. Because of these advantages, the micro-fabrication is thought to be a preferred carving process for improving the luminance of LED and hence attracts the attention of people in related fields (see, for example, Japanese Patent No. 4077312).

Meanwhile, it is known that a surface having a fine relief structure exhibits improved water-repellency. Further, it has recently reported that even a hydrophilic surface can be made water-repelling by forming a nano-scale relief structure thereon (see, E. Hosono et. al., J. Am. Cem. Soc. 127, (2005) 13458). This means that the light-extraction surface of LED becomes less hydrophilic if a fine relief structure is formed thereon.

As is evident from the above, if a nano-scale relief structure is formed on the light-extraction surface of LED, the light-extraction efficiency can be improved. On the other hand, however, it gives some problems. In a packaging procedure performed after forming the relief structure, the LED having the relief surface is sealed with resin. However, in that procedure, an air layer is often formed in the interface of resin/LED because the relief surface has poor wettability to the resin composition. As a result, the air layer in the interface may cause not only optical loss but also insufficient adhesion between the sealing resin and the light-extraction surface to decrease mechanical strength of the whole LED element.

Further, there is another problem. In the production process of LED elements, chips of LEDs are generally formed in a dicing procedure. For handling a diced chip, the chip is picked up by vacuum sucking the surface thereof. However, the relief structure described in E. Hosono et. al., J. Am. Cem. Soc. 127, (2005) 13458, for example, comprises such relatively sharp micro-projections as make it often difficult to pick up the chip by vacuum sucking.

### SUMMARY OF THE INVENTION

In view of the above problems, it is an object of the present invention to provide a semiconductor light-emitting element having both high light-extraction efficiency and excellent adhesion between the light-extraction surface and the sealing resin. Further, the present invention also aims at providing a process for production thereof.

One aspect of the present invention resides in a semiconductor light-emitting element comprising a semiconductor multilayered film in which plural semiconductor layers and an active layer are stacked, and a light-extraction surface which is provided on said semiconductor multilayered film and on which plural micro-projections are formed; wherein said micro-projections individually have flat faces at the same height level, and said flat faces are individually parallel to said semiconductor multilayered film.

Another aspect of the present invention resides in a process for production of a semiconductor light-emitting element, comprising the steps of:

stacking semiconductor layers to form a semiconductor multilayered film including an active layer,

forming an electrode on a part of said semiconductor multilayered film,

forming plural micro-projections on a light-extraction surface in the area where the electrode is not formed;

wherein

said step of forming plural micro-projections on a light-extraction surface further comprises the sub-steps of:

coating said light-extraction surface with a resin composition containing a block copolymer, to form a thin layer,

heating said thin layer to cause phase separation of said resin composition,

etching said light-extraction surface by use of a dot

pattern formed by the phase separation as a mask, and removing residues of said mask by etching.

### BRIEF DESCRIPTION OF THE DRAWINGS

FIG. 1 schematically illustrates sectional and top surface views of a semiconductor light-emitting element according to one embodiment of the present invention.

FIG. 2 schematically illustrates sectional shapes of micro-projections formed on a semiconductor light-emitting element according to one embodiment of the present invention.

FIG. 3 schematically illustrates an example process for producing a semiconductor light-emitting element according to one embodiment of the present invention.

FIG. 4 schematically illustrates a sectional view of the semiconductor light-emitting element in Example 2.

FIG. 5 schematically illustrates a process for producing the semiconductor light-emitting element in Example 2.

FIG. 6 shows examples of sectional electron micrographs of the resin-sealed semiconductor light-emitting elements in Example 2 and Comparative Example 2.

### DETAILED DESCRIPTION OF THE INVENTION

Embodiments of the present invention are described below in detail.

First, the following describes a relief structure formed on a light-extraction surface according to the present invention. In order to simplify the description of the present specification, the words “repellency” and “hydrophilicity” used hereinafter means particular properties to the liquid resin composition described later although they normally means properties to water.

Wettability, which is a property of how a liquid wets a solid surface or of how a liquid is repelled by a solid surface, can be defined by the contact angle, which is an angle at which the liquid meets the solid surface. If the contact angle is 0 to 90°, the solid surface is wetted with the liquid and hence is regarded as “hydrophilic”. On the other hand, if the contact angle is 90 to 180°, the solid surface repels the liquid and hence is regarded as “repelling”. The wettability depends on factors such as a chemical factor and a shape factor. The shape factor mainly controls the wettability of the relief structure according to the present invention, and is therefore described below in detail.

The contact angle on a solid composed of two different components is given by the following formula (1) of Cassie's law:

cos θ=f₁ cos θ₁+f₂ cos θ₂ (1).

In the above formula, θ is an apparent contact angle on the composite solid; θ₁ and θ₂ are true contact angles on the components 1 and 2, respectively; and f₁ and f₂ are area size ratios of the components 1 and 2, respectively, under the condition of f₁+f₂=1. It is evident from the formula (1) that the contact angle on a composite solid of two different components is between the contact angles (θ₁, θ₂) on the individual components.

If the formula (1) is applied to the case where a relief structure on a LED element is sealed with a liquid resin composition, the contact angle on the relief structure can be represented by the formula (2):

cos θ=fₛₑₘᵢ cos θₛₑₘᵢ+(1−fₛₑₘᵢ) cos θₐᵢᵣ (2)

provided that the micro-projections and the micro-depressions are regarded as a semiconductor (semi) layer and an air layer, respectively.

Since a liquid in air generally forms spherical drops by the surface tension, the contact angle θₐᵢᵣ between the liquid and air is more than 90° and hence the second term in the right side is generally negative. The formula (2) therefore indicates that, according to decrease of the area size ratio fₛₑₘᵢ of the micro-projections, cos θ in the left side decreases and finally reaches a negative value. This means that the apparent contact angle between the relief structure and the resin composition gradually increases to impair the wettability of the resin composition.

In a semiconductor light-emitting element according to one embodiment of the present invention, the area size ratio of micro-projection fₛₑₘᵢ can be increased so as to improve the wettability on a surface provided with the relief structure. Specifically, the micro-projection tops, which the resin composition is brought into contact with, are flattened to improve the wettability on the whole surface.

### Embodiment of Semiconductor Light-Emitting Element

There is no particular restriction on the semi-conductor light-emitting element of the present invention, as long as its light-emitting efficiency can be improved by forming a relief structure on the light-extraction surface thereof. However, favorable effects can be expected if the element is a light-emitting diode (LED) or a laser diode (hereinafter, often referred to as LD).

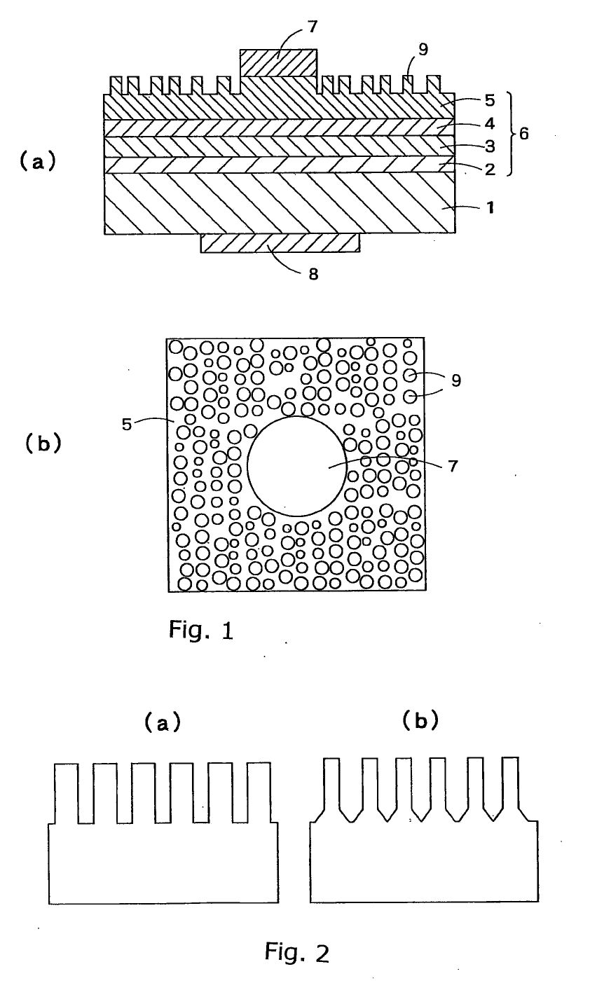

FIG. 1 illustrates a structure of a LED element according to one embodiment of the present invention. FIGS. 1(a) and (b) are sectional and top surface views, respectively, showing an example constitution of the LED element according to one embodiment of the present invention. As shown in FIG. 1(a), the LED element comprises a crystal substrate 1, an n-type semiconductor (clad) layer 2, an active layer 3, a p-type semiconductor (clad) layer 4, and a current-spreading layer 5, stacked in this order. Hereinafter, those layers may be unifyingly referred to as a semiconductor multilayered film 6. The current-spreading layer is not essential, but is preferably provided for the purpose of enhancing the emission efficiency. If provided, the current-spreading layer is normally formed on the top, namely, on the outermost layer of the semiconductor multilayered film. In the LED element, the multilayered film having the above structure serves as a light-emitting unit. On a part of the current-spreading layer 5, a p-side electrode layer 7 is formed. On the bottom surface of the crystal substrate 1, an n-type electrode layer 8 is provided. The electrode layers 7 and 8 are brought into ohmic contact with the current-spreading layer 5 and the crystal substrate 1, respectively. The LED element according to the present invention may have not only the above fundamental constitution but also essentially the same constitution as any known light-emitting element. However, on the bare surface of the current-spreading layer 5, the LED element of the present invention has fine micro-projections 9 formed in the area not provided with the electrode. Each of the micro-projections 9 has a flat face at the same height level, and each flat face is essentially parallel to the semiconductor multilayered film 6. In the present invention, the term “light-extraction surface” means an outermost surface from which the element emits light to the outside and which is a surface of the multilayered film opposite to the other surface that keeps in contact with the substrate. Accordingly, the light-extraction surface of the example element shown in FIG. 1(a) corresponds to the surface of the current-spreading layer 5. However, the light-extraction surface is not restricted to the current-spreading layer surface, and may correspond to any surface depending on the structure of the element. For example, if the light-emitting element comprises no current-spreading layer, the light-extraction surface may directly correspond to the outermost surface of the semiconductor multi-layered film having no current-spreading layer. Further, the light-extraction surface may correspond to the surface of an intermediate layer other than the current-spreading layer, such as a surface of a contact layer or of a protective film.

The micro-projections 9 are not necessarily restricted in arrangement, but are preferably positioned not in regular intervals but in random intervals having some distribution as shown in FIG. 1(b). If the relief structure comprises the micro-projections thus disposed at random, light coming not only at a particular incident angle but also in a wide incident angle range can be diffracted at the interface between the element and the outside. The intervals among the micro-projections 9 are preferably adjusted according to the emitted light wavelength. Specifically, the average interval among the micro-projections 9 is preferably in the range from 1/(refractive index of the external medium +refractive index of the semiconductor multilayered film surface) of the emitted light wavelength to twice of that wavelength. Here, the “semiconductor multilayered film surface” does not mean the surface exposed to the outside but it means the skin-deep layer near to the surface, namely, the top outermost layer of the semiconductor multilayered film. Further, the micro-projections preferably have circular flat top faces. Each flat face may be not in a circular shape but in a polyhedral or elliptical shape. However, in view of easiness of production, the flat faces preferably have circular shapes. Furthermore, the flat faces of the micro-projections preferably have not the same size but random sizes. If the micro-projections have flat faces of distributed area sizes, light-scattering can be caused by density fluctuation to further improve the light-extraction efficiency. In that case, however, the flat faces of the micro-projections preferably have an average diameter of 1/10 or more of the emitted light wavelength so as to avoid Rayleigh scattering. Here, if one flat face is not in a circular shape, a diameter of the circle having the same area size as the flat face is regarded as the diameter of that flat face. The reason why Rayleigh scattering is avoided is because the scattering is so isotropic that the light emitted from the inside to the outside is partly reflected back to the inside to impair the light-extraction efficiency.

Further, as indicated by the formula (2), the wettability of the resin composition on the relief surface becomes worse in accordance with decrease of the area size ratio of the flat faces, namely, in accordance with decrease of the area size ratio in which the flat faces of the micro-projections occupy the whole light-extraction surface. The present inventors have studied and finally found that both excellent wettability and high light-extraction efficiency are realized if the flat faces of the micro-projections occupy the light-extraction surface in an area size ratio of 30 to 70% in total.

FIG. 2 schematically illustrates sectional views of the light-extraction surfaces provided with the micro-projections 9. The top faces of the formed micro-projections are flattened and essentially parallel to the semiconductor layer. The micro-projections may be in the sectional shapes of pillars (a) or of pillars standing on mesa-shaped bases (b) from the viewpoint regarding the semiconductor layers as horizontal. Here, the average height of the micro-projections is preferably as 0.6 to 1.5 times as long as the wavelength of light given off from the light-emitting element.

If the micro-projections are in the shapes of columns standing on mesa- or taper-shaped bases as shown in FIG. 2 (b), the refractive index gradually varies in the horizontal direction so that the emission efficiency is not impaired by reflection. This means that the above structure gives not only light-diffraction effect but also anti-reflection effect, and accordingly furthermore improves the light-extraction efficiency.

In the case where the pillars are formed on the mesa-shaped bases, there is no particular restriction on the concrete structure thereof. However, in order to obtain high anti-reflection effect, the base may have a preferred structure. For example, if the pillars are in the shapes of columns, the diameters of the columns are preferably in the range of ⅓ to 9/10 of those of the bottoms of the mesa-shaped bases. The diameters of the bottoms of the mesa-shaped bases are preferably in the range from 1/(refractive index of the external medium+refractive index of the substrate) of the emitted light wavelength to the same as that wavelength. Further, the heights of the mesa-shaped bases are in the range of 1/10 to ⅕ of the emitted light wavelength. JP-A 2006-108635 (KOKAI) describes the structures and effects of the mesa-shaped bases having the above structure.

The semiconductor layers included in the semiconductor light-emitting element may be made of known materials such as GaP, InGaAlP, AlGaAs, GaAsP and nitride semiconductors. There is no particular restriction on the process for forming the layers, and they can be formed by, for example, metalorganic chemical vapor deposition (MOCVD) method, molecular beam epitaxy (MBE) method or vapor phase epitaxy (VPE) method. The crystal substrate of the light-emitting element is made of, for example, gallium arsenide, sapphire, silicon, silicon nitride, silicon carbide or zinc oxide. The light-emitting element described above has a structure in which the upper and lower electrodes are of p- and n-types, respectively. However, it by no means restricts the present invention. The upper and lower electrodes may be of n- and p-types, respectively. If necessary, a buffer layer may be provided between the crystal substrate and the semiconductor layers. Further, a current spreading layer and/or a contact layer may be formed between the crystal substrate and the semiconductor layers. The semiconductor multilayered film may have either a simple p-n junction structure or any other known structure such as the double-hetero (DH) structure, the single quantum well (SQW) structure or the multi-quantum well (MQW) structure. The electrode layers of the light-emitting element according to the present invention are preferably made of material capable of keeping in ohmic contact with semiconductors. The material is preferably at least one metal or alloy selected from the group consisting of Au, Ag, Al, Zn, Ge, Pt, Rd, Ni, Pd and Zr, and is preferably capable of forming a mono- or multi-layered structure.

### [Process for Production of Semiconductor Light-Emitting Element]

As described above, a very fine relief structure is formed on the light-extraction surface of the light-emitting element according to one embodiment of the present invention. The relief structure has fineness beyond the resolution limit of photo-lithography generally adopted, and hence is difficult to form without employing a special method. However, a semi-conductor light-emitting element comprising the very fine relief structure on its light-extraction surface can be advantageously produced according to a nano-fabrication method utilizing self-assembling of materials used therein. Specifically, it is particularly preferred to adopt a nano-fabrication method disclosed in Patent documents 1 and JP-A 2006-108635 (KOKAI). The disclosed method employs a micro-structure formed by phase separation of block copolymer.

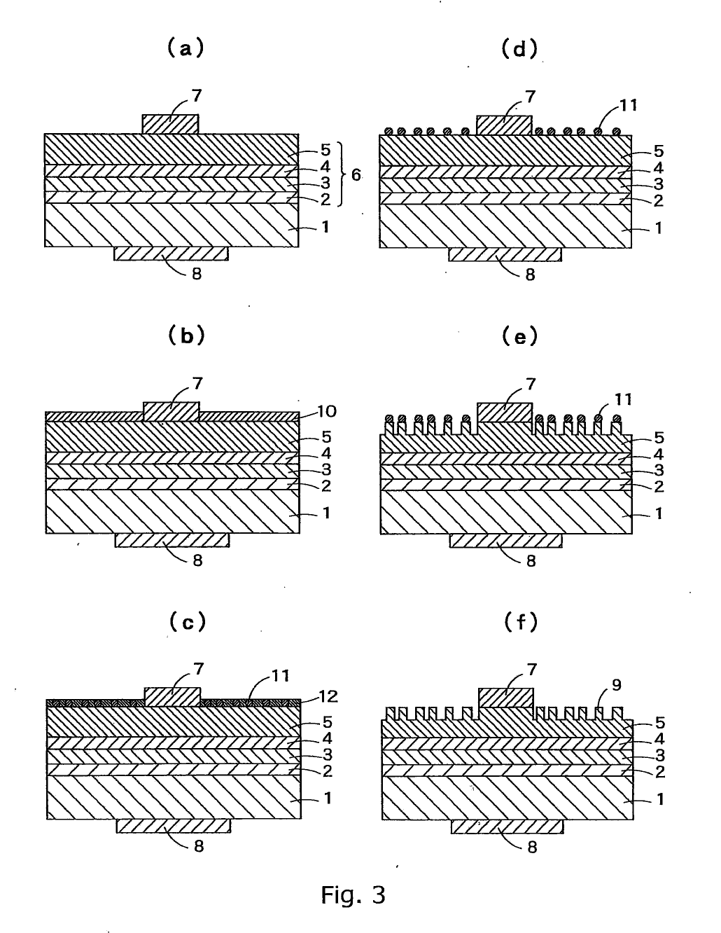

The production process employing a micro-pattern formed by phase separation of block copolymer is described below in detail by referring to FIG. 3.

First, a DH structure comprising clad layers 2, 4 and an active layer 3 placed between them is formed on a substrate 1. After that, a current spreading layer 5 is formed thereon to provide a semiconductor multilayered film 6 on the substrate 1. Further, a p-side electrode layer 7 is formed on a part of the current spreading layer 5, and an n-side electrode layer 8 is provided on the bottom of the substrate 1 (FIG. 3(a)).

Subsequently, the current spreading layer 5 is spin-coated with a resin composition solution containing a block copolymer diluted with an organic solvent. The coated solution is then heated on a hot-pate until the organic solvent evaporates, so that a resin composition film 10 containing the block copolymer is formed on the current spreading layer 5 (FIG. 3(b)).

The block copolymer and solvent contained in the resin composition are properly selected depending on the size of the aimed relief structure and the like, and details thereof are described later.

Thereafter, in an oven under nitrogen gas atmosphere, the resin composition film is heated at a temperature higher than the glass transition temperatures of polymer components constituting the block copolymer, so that the block copolymer can cause micro-phase separation (FIG. 3(c)). The phase separation forms a dot-pattern. The block copolymer is beforehand selected so that the polymer component of the dot parts 11 may be superior in etching durability to that of the matrix part 12, and thereby only the matrix part 12 can be removed to leave the dot parts 11 by reactive ion etching (RIE) with a proper etching gas (FIG. 3(d)).

After that, the underlying current spreading layer 5 is subjected to RIE in a Cl₂ type gas by use of the polymer dot parts 11 as a mask (FIG. 3(e)). If the etching conditions are so controlled that the etching proceeds anisotropically, micro-projections can be formed in columnar shapes. For forming mesa-shaped bases, isotropic sputtering with Ar is carried out for a proper time after the columnar micro-projections are formed by the anisotropic etching. The process can thus provide columnar micro-projections standing on mesa-shaped bases. JP-A 2006-108635 (KOKAI) discloses this process in detail.

Finally, the remaining polymer dot parts 11 are removed by oxygen ashing to form micro-projections 9 on the current spreading layer 5 (FIG. 3(e)). The areas covered with the polymer dot parts 11 in the previous step are flattened by the ashing to obtain a semiconductor light-emitting element of the present invention.

The above order of the procedures by no means restricts the process of the present invention for producing a semiconductor light-emitting element. For example, the micro-projections 9 may be formed on the current spreading layer 5 before the p-type electrode layer 7 is formed. Accordingly, even if the order of the steps is changed depending on necessity, the semiconductor light-emitting element of the present invention can be produced.

Further, it is also possible to adopt a pattern transfer method in the process for production of a light-emitting element according to one embodiment of the present invention. The pattern transfer method is explained below in concrete. Normally, because of a small difference in etching selectivity between the polymer layer and the compound semiconductor layer, it is difficult to form a relief structure of high aspect ratio. To cope with this problem, the pattern transfer method is proposed. In the pattern transfer method, an inorganic composition film serving as an intermediate layer is formed on the current spreading layer, and is then coated with the above-described resin composition containing a block copolymer. The coated resin composition is made to cause micro-phase separation, and then subjected to a RIE or wet-etching process so as to form a dot-pattern of the block copolymer on the inorganic composition film. Subsequently, the formed dot-pattern is transferred onto the compound semiconductor layer. Since forming a mask of inorganic composition having higher etching resistance than the polymer, the pattern transfer method enables to form a relief structure of high aspect ratio on the current spreading layer. Accordingly, the inorganic composition film preferably has higher resistance against RIE with O₂, Ar or Cl₂ gas than the polymer components of the block copolymer. For example, the inorganic composition film is a silicon, silicon nitride or silicon oxide layer formed by sputtering, by vacuum deposition or by chemical vapor deposition. Further, it may be formed by spin-coating of siloxene polymer, of polysilane, or of spin-on glass (SOG). JP-A 2001-151834 KOKAI) discloses the pattern transfer method in detail.

### [Resin Composition Containing Block Copolymer]

In order to produce a semiconductor light-emitting element having a fine relief structure on its light-extraction surface, it is most preferred for the block copolymer to have a morphology of a dot structure in the present invention.

As described above, the micro-projection in the relief structure of the present invention preferably has a size (a diameter of corresponding circle) of more than 1/10 of the emitted light wavelength. Accordingly, if the emitted light has a wavelength ranging from UV to IR (300 to 900 nm), the size of the micro-projection is preferably at least 30 to 90 nm. This corresponds to the dot size in the dot pattern formed by the phase separation. The block copolymer used in the present invention preferably has a molecular weight of 500,000 to 3,000,000. If having a molecular weight of more than 3,000,000, the block copolymer dissolved in an organic solution is so viscous that it cannot be evenly spin-coated. The block copolymer of too high molecular weight thus causes troubles in coating, and is hence not practical.

Further, if the block copolymer has a high molecular weight, it often takes long time to cause the micro-phase separation by heating. In that case, since the heating procedure must be carried out for a limited time in a practical production process, the phase separation may proceed insufficiently and, as a result, some dots in the pattern may be connected or combined with each other. If the dot pattern used in the process is formed by insufficient phase separation, the resultant semiconductor light-emitting element has such an unfavorable relief pattern as impairs the light-extraction efficiency. In order to prevent the block copolymer from causing insufficient phase separation, it is preferred to incorporate an additive polymer into the resin composition containing the block copolymer. The additive polymer is a low-molecular weight homopolymer composed of one block component selected from the plural block components constituting the block copolymer. The micro-phase separation can be thus promoted, and Japanese Patent No. 4077312 describes the promotion of micro-phase separation.

The resin composition containing the block copolymer is dissolved in a solvent, which is preferably a good solvent of both polymer components constituting the block copolymer. That is because repulsion between two polymer chains is generally proportional to the square of the difference between their solubility parameters. Since the solvent can dissolve both polymer components enough to reduce the difference between their solubility parameters, the repulsion is lowered to increase free energy of the system and consequently to promote the phase separation. The solvent capable of dissolving the block copolymer and, if necessary, the additional homopolymer preferably has a boiling point of 150° C. or more. Examples of the solvent include ethyl cellosolve acetate (ECA), propylene glycol monomethyl ether acetate (PGMEA) and ethyl lactate EL).

The block copolymer usable in the present invention is preferably constituted of an aromatic polymer and an acrylic polymer in combination. That is because these two polymers generally have different etching rates in RIE treatment with a properly selected gas. This is described in Japanese Patent No. 4077312. Examples of the aromatic polymer include polystyrene (PS), polyvinylnaphthalene, polyhydroxystyrene and derivatives thereof. Examples of the acrylic polymer include alkyl methacrylate such as polymethyl methacrylate (PMMA), polybutyl methacrylate, polyhexyl methacrylate; polyphenyl methacrylate, polycyclohexyl methacrylate, and derivatives thereof. These methacrylates can be replaced with acrylates. Among them, a block copolymer of PS and PMMA is preferred because it can be easily prepared and the molecular weight of each polymer component is easily controlled.

One embodiment of the present invention makes it possible to flatten the top faces of micro-projections in a relief structure formed on the light-extraction surface of a semi-conductor light-emitting element such as a LED. Consequently, this invention enables to improve adhesion between the light-extraction surface and a sealing resin in the element, and accordingly to prevent formation of an air layer when the element is sealed with the resin. This means that the invention can prevent the air layer from lowering the luminance and also can prevent the sealing resin from coming off. Further, since the present invention ensures flat surfaces on the tops of micro-projections in a relief structure formed on the light-extraction surface, the chips can be easily picked up by vacuum sucking, so as to improve the production yield after the dicing procedure.

Additional advantages and modifications will readily occur to those skilled in the art. Therefore, the invention in its broader aspects is not limited to the specific details and representative embodiments shown and described herein.

Accordingly, various modifications may be made without departing from the spirit or scope of the general inventive concept as defined by the appended claims and their equivalents.

### Example 1

### Example 1 and Comparative Example 1

The following procedures gave a LED element in which columnar micro-projections were formed on its current spreading layer. The produced LED element corresponds to the element shown in FIG. 1.

As the crystal substrate 1, an n-type GaP substrate was used. An n-GaAlP layer as the n-type semiconductor layer 2 was formed thereon by MOCVD method. Subsequently, an InGaAlP layer as the active layer 3 and a p-InGaAlP layer as the p-type semiconductor layer 4 were successively formed thereon. Finally, a p-GaP layer as the current spreading layer 5 was formed on the p-type semiconductor layer, to produce a semiconductor multilayered film 6 on the substrate 1. Thereafter, a p-side electrode layer 7 was formed on the current spreading layer 5 by vacuum deposition, and then an n-side electrode layer 8 was provided on the whole bottom surface of the n-type GaP substrate. The p-side and n-side electrode layers 7, 8 were fabricated to be in desired shapes, and subsequently heated to bring the interfaces of n-side electrode layer/n-type GaP substrate and of p-GaP layer/p-side electrode layer into ohmic contact.

The following describes in detail a step of forming the relief structure on the current spreading layer on the light-extraction side. The procedures described below correspond to those shown in FIG. 3.

First, a PS-PMMA block copolymer (Mn=895,000, Mn/Mw=1.08) was diluted with PGMEA to prepare a 4.0 wt % solution. Further, a PMMA homopolymer (Mn=1,720, Mn/Mw=1.15) was diluted with PGMEA to prepare a 4.0 wt % solution, and a PS homopolymer (Mn=1,790, Mn/Mw=1.06) was diluted with PGMEA to prepare a 4.0 wt % solution. The solutions were individually filtrated through a 0.2 μm mesh, and then mixed in the weight ratio of 4 (PS-PMMA): 6 (PMMA): 1 (PS) to prepare a resin composition solution containing the block copolymer.

The prepared solution was spin-coated on the p-GaP current spreading layer 5, and heated on a hot-plate at 110° C. for 90 seconds to form a resin composition film 10 containing the block polymer (FIG. 3(b)). Thereafter, the sample was placed in an oven, and subjected to phase separation annealing at 250° C. for 8 hours under nitrogen gas atmosphere (FIG. 3(c)). The obtained phase separation pattern had a morphology in which microdomains of PS in the shapes of dots were dispersed in a matrix of PMMA. The dotted microdomains had an average diameter of approx. 80 nm, and were arranged in intervals of 150 nm on average.

After that, the PMMA matrix part 12 in the block copolymer was selectively removed by oxygen plasma RIE (O₂ flow: 30 sccm, pressure: 100 mTorr, bias: 100 W), to obtain a mask of the PS dot parts 11 (FIG. 3(d)). This procedure is based on the fact that PMMA is etched by oxygen plasma RIE three times as fast as PS, and thereby the PMMA matrix part 12 can be completely removed to leave only the PS dot parts 11.

Subsequently, the p-GaP layer 5 covered with the PS dots was etched by means of induced coupled plasma (ICP)-RIE system (FIG. 3(e)) under the conditions of Cl₂ flow: 5 sccm, Ar flow: 15 sccm, pressure: 5 mTorr, bias: 100 W, ICP: 30 W. After the etching procedure, oxygen ashing was carried out for 1 minute to remove the PS dot parts 11 and thereby to form micro-projections 9 on the p-GaP layer 5 (FIG. 3(f)). The semiconductor light-emitting element thus obtained had a light-emitting surface provided with micro-projections whose average height was 250 nm, which were arranged in intervals of 150 nm on average, and whose flat faces occupied 40% (area size ratio) of the light-extraction surface. The micro-projections had columnar shapes corresponding to the shapes shown in FIG. 2(a).

The LED element produced in Example 1 was evaluated. For the purpose of that, a comparative LED element (Comparative Example 1) was prepared. The comparative element had the same structure as the element of Example 1 except that the light-extraction surface was not fabricated.

The light-extraction surface of each LED element was sealed with an epoxy resin, and then the total emission intensity was measured by means of a chip tester. As a result, the LED element of Example 1 emitted light 1.46 times as intense as the comparative element, whose light-extraction surface was not fabricated. Further, a section of the LED element of Example 1 after sealed with the resin was observed with a scanning electron microscope (SEM), and consequently no air layer was seen between the light-extraction surface and the sealing resin. Accordingly, it was verified that the element and the sealing resin were firmly combined with each other.

As described above, a semiconductor light-emitting element produced according to the process of the present invention has high light-extraction efficiency and excellent adhesion with the sealing resin, as compared with a light-emitting element having no relief structure on its light-extraction surface.

### Example 2 and Comparative Example 2

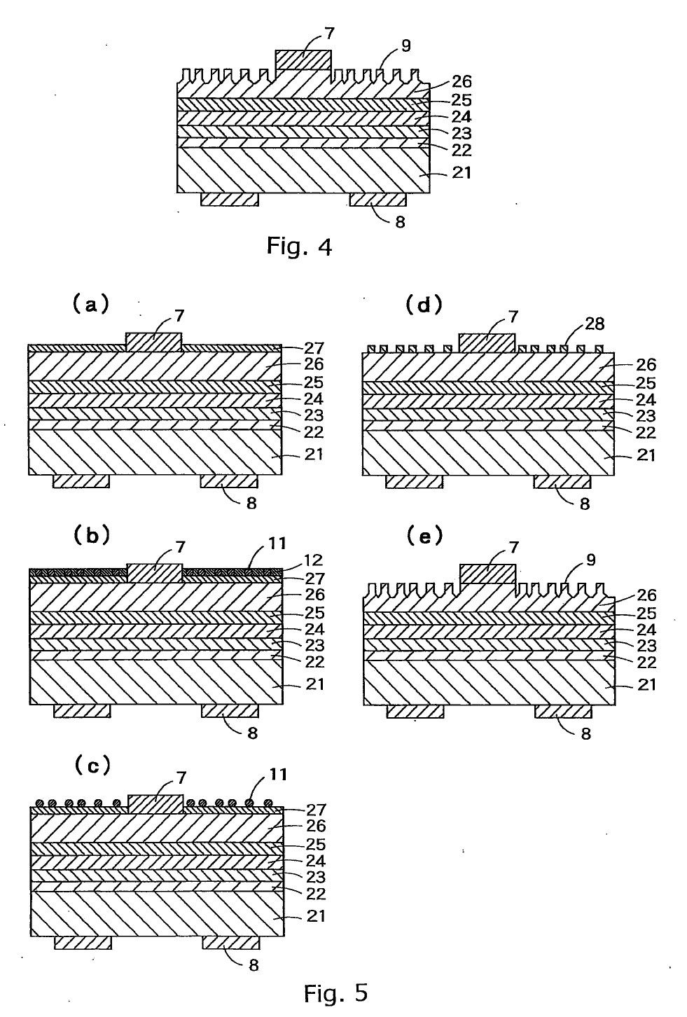

The following procedures gave a semiconductor light-emitting element in which columnar micro-projections standing on mesa-shaped bases were formed on its light-extraction surface. In this example, the pattern transfer method was adopted to form the micro-projections of high aspect ratios. FIG. 4 shows a sectional view of the element produced in this element.

On an n-type GaN substrate 21, an n-type GaN buffer layer 22, an n-type GaN clad layer 23, an MQW active layer 24 of INGaN/GaN, a p-type AlGaN cap layer 25 and a p-type GaN contact layer 26 were successively formed by MOCVD method. Subsequently, a p-side electrode layer 7 was formed on the p-type GaN contact layer 26 by vacuum deposition, and then an n-side electrode layer 8 was provided on the whole bottom surface of the substrate 21. The p-side and n-side electrode layers 7, 8 were then fabricated to be in desired shapes, and thereafter heated to bring into ohmic contact with the element.

The following describes in detail a step of forming the relief structure by use of the pattern transfer method. The procedures described below correspond to those shown in FIG. 5.

First, the formed p-type GaN contact layer 26 was spin-coated at 1800 rpm for 30 seconds with a 6.0 wt % solution of SOG diluted with ethyl lactate, and then heated on a hot-plate at 110° C. for 90 seconds to evaporate ethyl lactate. Subsequently, the sample was fired under nitrogen gas atmosphere at 300° C. for 30 minutes to form a 100 nm-thick SOG film 27 on the p-type GaN contact layer 26. Thereafter, a resin composition film was formed on the SOG film 27 in the same manner as in Example 1, and then heated on a hot-pate and subjected to phase separation annealing under nitrogen gas atmosphere (FIG. 5(b)). The block copolymer in the resin composition thus caused micro-phase separation to give a dot pattern comprising polymer dot parts 11 and a PMMA matrix part 12. The PMMA matrix part 12 was then completely removed by the RIE treatment in the same manner as in Example 1 (FIG. 5(c)), and thereafter the pattern of the polymer dot parts 11 was transferred onto the underlying SOG film 27 by RIE with F-containing gases (CF₄ flow: 15 sccm, CHF₃ flow: 15 sccm, 10 mTorr, 100 W), to form a SOG mask 28 (FIG. 5(d)). The remaining PS polymer dot parts 11 were removed by oxygen ashing. After that, the underlying p-type GaN contact layer 26 was subjected to ICP-RIE etching by use of the SOG mask 28, to form micro-projections 9 (FIG. 5(e)). In the early stage of this ICP-RIE etching procedure, the etching conditions were set to be the same as in Example 1 to form columnar micro-projections (FIG. 3(e)). Subsequently, the feet of the columnar micro-projections were fabricated by Ar sputtering (Ar flow: 30 sccm, 10 mTorr, bias: 100 w), to form mesa-shaped bases. Because of this Ar sputtering, the tops of the micro-projections were seemingly sharpened. However, since the micro-projections were covered with the mask, only the masking SOG caps on the tops were sharpened and the tops themselves were not sharpened. Thereafter, the mask was removed to form micro-projections standing on mesa-shaped bases shown in FIG. 2(b). The formed micro-projections 9 had flat top faces, were arranged in intervals of 150 nm on average, were 450 nm high, and occupied 45% of the light-extraction surface.

As Comparative Example 2, another comparative LED element was prepared. The comparative element had the same structure as the element of Example 2 except that the micro-projections were sharpened by additionally conducting the Ar sputtering (Ar flow: 30 sccm, 10 mTorr, bias: 100 w) after the procedures of Example 2.

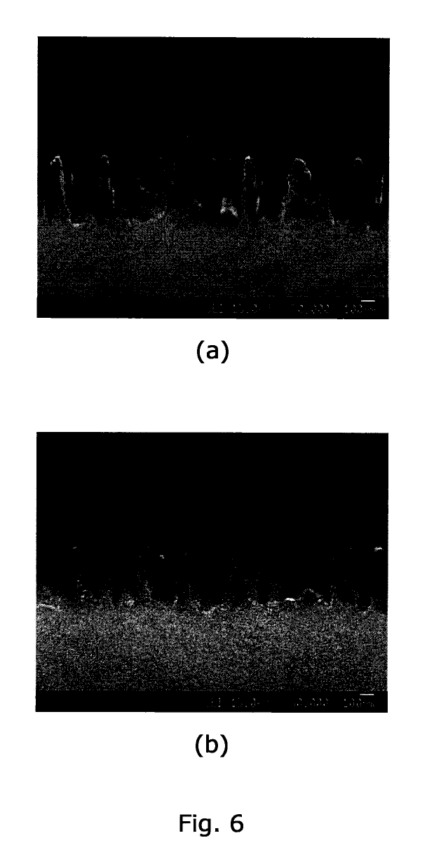

With respect to each of the LED elements of Example 2 and Comparative Example 2, the light-extraction surface was sealed with an epoxy resin, and then the total emission intensity was measured by means of a chip tester. As a result, the LED element of Example 2 and that of Comparative Example 2 emitted light 1.76 times and 1.68 times, respectively, as intense as the comparative element whose light-extraction surface was not fabricated. Further, a section of each LED element was observed in the same manner as in example 1, and consequently a few air layers were seen between the relief structure and the resin in the element of Comparison Example 2 (FIG. 6(a)) while no air layer was seen in that of Example 2 (FIG. 6(b)).

As shown by the above Examples, when the element is sealed with a resin, formation of an air layer can be prevented by flattening the top faces of the micro-projections formed on the light-extraction surface. Consequently, according to the present invention, the element can keep high light-extraction efficiency even after sealed with a resin, and further the production yield can be improved.

### Example 3

With respect to five different LED elements, the present example evaluated the light-extraction efficiency and the adhesion between the element and the sealing resin. Those elements were different from each other in the area size ratio of the flat top faces of the columnar micro-projections. Each element produced in the present example had the same structure as that of Example 1.

The procedures of Example 1 were repeated except that the etching time of the oxygen plasma RIE was changed to shrink the polymer dot parts 11 and thereby to control the area size ratio of the flat faces. The area size ratios of the flat faces in the elements were approx. 28%, 35%, 50%, 60% and 72%. The micro-projections of each LED element were arranged in intervals of 150 m on average, and were approx. 200 nm high.

With respect to each LED element, the light-extraction surface, on which the micro-projections were provided, was sealed with an epoxy resin, and then the total emission intensity was measured by means of a chip tester. Further, a section of each element was observed. The results were as set forth in Table 1:

TABLE 1

| | area size ratio (%) | | | | |
|---|---|---|---|---|---|
| | 28 | 35 | 50 | 63 | 72 |
| adhesion to resin | good | excellent | excellent | excellent | excellent |
| emission intensity | 1.05 | 1.30 | 1.42 | 1.27 | 1.08 |

As a result, the adhesion between the relief structure and the resin was found to increase according as the area size ratio increased. This is because the wettability of the resin was improved according to increase of the area size ratio. The results indicate that the area size ratio is preferably 30% or more. It was also found that, if the area size ratio was too small, the micro-projections were so thin that they were partly liable to collapse. In contrast, if the area size ratio was too large, the micro-projections were so thick that they were liable to connect each other.

On the other hand, as for the emission, the intensity became the highest at the area size ratio of 50% and decreased at the area sizes smaller or larger than that. This is presumed to be because the adhesion to resin was liable to decrease and the micro-projections were liable to collapse if the area size ratio was small and because the adjacent micro-projections were liable to connect each other in the etching procedure to impair the diffraction effect if the area size ratio was large.

As described above, the adhesion to resin and the light-extraction efficiency greatly depend on the area size ratio of the flat faces of the micro-projections. Accordingly, if the area size ratio is optimally controlled, it is possible to form a relief structure excellent in both of the adhesion to resin and the light-extraction efficiency. It is found to be optimal for the flat faces of the micro-projections according to the present invention to occupy the light-extraction surface in an area ratio of 30% to 70% in total.

1. A semiconductor light-emitting element comprising a semiconductor multilayered film in which plural semiconductor layers and an active layer are stacked, and a light-extraction surface which is provided on said semiconductor multilayered film and on which plural micro-projections are formed; wherein said micro-projections individually have flat faces at the same height level, said flat faces are individually parallel to said semiconductor multilayered film, and said flat faces occupy said light-extraction surface in an area size ratio of 30 to 70% in total.

2. The element according to claim 1, wherein said micro-projections are positioned at random on said light-extraction surface.

3. The element according to claim 1, wherein each of said flat faces has a random size.

4. The element according to claim 1, wherein said micro-projections are arranged in intervals having an average length in the range from 1/(refractive index of the external medium+refractive index of the semiconductor multilayered film surface) of the emitted light wavelength to twice of said wavelength.

5. The element according to claim 1, wherein the average diameter of said flat faces is 1/10 or more of the emitted light wavelength under the condition that a diameter of the circle having the same area size as each flat face is regarded as the diameter of each corresponding flat face.

6. The element according to claim 1, wherein said micro-projections have an average height in the range of 0.6 to 1.5 times as long as the emitted light wavelength.

7. The element according to claim 1, wherein said micro-projections are in the shapes of columns.

8. The element according to claim 1, which is a light-emitting diode element or a laser diode element.

9. A process for production of a semiconductor light-emitting element, comprising the steps of:
stacking semiconductor layers to form a semiconductor multilayered film including an active layer,
forming an electrode on a part of said semiconductor multilayered film,
forming plural micro-projections on a light-extraction surface in the area where the electrode is not formed;
wherein
said step of forming plural micro-projections on a light-extraction surface further comprises the sub-steps of:
coating said light-extraction surface with a resin composition containing a block copolymer, to form a thin layer,
heating said thin layer to cause phase separation of said resin composition,
etching said light-extraction surface by use of a dot pattern formed by the phase separation as a mask, and
removing residues of said mask by etching.

10. The process according to claim 9, wherein said light-extraction surface is a current-spreading layer formed on said semiconductor multilayered film.

11. The process according to claim 9, wherein said block copolymer is constituted of an aromatic polymer and an acrylic polymer in combination.

12. The process according to claim 9, wherein the sub-step of etching said light-extraction surface is carried out by anisotropic etching to form micro-projections in the shapes of columns.
